(19) United States
(12) Patent Application Publication
(10) Pub. No.: US 2021/0358934 A1
(43) Pub. Date: Nov. 18, 2021

(54) NON-VOLATILE MEMORY STRUCTURE

(71) Applicant: Powerchip Semiconductor Manufacturing Corporation, Hsinchu (TW)

(72) Inventors: Jung-Sung Chao, Taichung City (TW); Hung-Kwei Liao, Taoyuan City (TW); Chen-Chiang Liu, Hsinchu County (TW)

(73) Assignee: Powerchip Semiconductor Manufacturing Corporation, Hsinchu (TW)

(21) Appl. No.: 17/093,585

(22) Filed: Nov. 9, 2020

(30) Foreign Application Priority Data
May 15, 2020 (TW) 109116212

(51) Int. Cl. H01L 27/11568

(52) U.S. Cl. CPC H01L 27/11568

(57) ABSTRACT

A non-volatile memory structure including a substrate, a select gate, a control gate, and a charge storage layer is provided. There is a trench in the substrate. The select gate is disposed in the trench. The control gate is disposed in the trench and is located on the select gate. The charge storage layer is disposed between the control gate and the select gate and between the control gate and the substrate. The charge storage layer includes a nitride layer, a first oxide layer, and a second oxide layer. The nitride layer is disposed on the select gate and on two sidewalls of the trench. The nitride layer is a continuous structure. The first oxide layer is disposed between the nitride layer and the select gate. The second oxide layer is disposed between the control gate and the nitride layer.

### CROSS-REFERENCE TO RELATED APPLICATION

This application claims the priority benefit of Taiwan application serial no. 109116212, filed on May 15, 2020. The entirety of the above-mentioned patent application is hereby incorporated by reference herein and made a part of this specification.

### BACKGROUND

### Technical Field

The invention relates to a memory structure and a manufacturing method thereof, and particularly relates to a non-volatile memory structure and a manufacturing method thereof.

### Description of Related Art

Since a non-volatile memory may be subjected to data storing, reading and erasing operations for many times, and has advantages of no disappearing of stored data in case of power supply interruption, a short data access time and low power consumption, etc., it is a kind of memory widely used in personal computers and electronic devices.

A patent literature 1 (U.S. Pat. No. 7,592,224 (U.S. 7,592,224 B2)) discloses a storage device. The storage device of the patent literature 1 has a vertical channel, and a select gate and a control gate located in a trench, and uses discontinuous storage elements (DSE) (for example, silicon nanocrystals) to store charges. Moreover, a patent literature 2 (U.S. Pat. No. 8,710,576 (U.S. Pat. No. 8,710,576 B2)) discloses a flash memory. The flash memory of the patent literature 2 has a vertical channel, and uses an oxide/nitride/oxide (ONO) structure to store charges.

However, how to further improve electrical performance and an integration degree of the memory device is a goal of continuous efforts in the industry at present.

### SUMMARY

The invention is directed to a non-volatile memory structure, which is capable of effectively improving electrical performance and an integration degree of memory devices.

The invention provides a non-volatile memory structure including a substrate, a select gate, a control gate, and a charge storage layer. There is a trench in the substrate. The select gate is disposed in the trench. The control gate is disposed in the trench and is located on the select gate. The charge storage layer is disposed between the control gate and the select gate and between the control gate and the substrate. The charge storage layer includes a nitride layer, a first oxide layer, and a second oxide layer. The nitride layer is disposed on the select gate and on two sidewalls of the trench. The nitride layer is a continuous structure. The first oxide layer is disposed between the nitride layer and the select gate. The second oxide layer is disposed between the control gate and the nitride layer.

In an embodiment of the invention, in the non-volatile memory structure, a material of the select gate is, for example, doped polysilicon.

In an embodiment of the invention, in the non-volatile memory structure, the control gate has a protrusion protruding from a top surface of the substrate.

In an embodiment of the invention, in the non-volatile memory structure, a maximum width of the protrusion is greater than a maximum width of the trench.

In an embodiment of the invention, the non-volatile memory structure further includes a spacer. The spacer is disposed on a sidewall of the protrusion.

In an embodiment of the invention, in the non-volatile memory structure, the spacer is a single-layer structure.

In an embodiment of the invention, in the non-volatile memory structure, the spacer is a multi-layer structure.

In an embodiment of the invention, in the non-volatile memory structure, a part of the control gate is located on a top surface of the substrate.

In an embodiment of the invention, in the non-volatile memory structure, a cross-sectional shape of the control gate is a T-shape.

In an embodiment of the invention, in the non-volatile memory structure, a material of the control gate is, for example, doped polysilicon.

In an embodiment of the invention, in the non-volatile memory structure, the charge storage layer is conformally disposed on two sidewalls of the trench and on a top surface of the select gate.

In an embodiment of the invention, in the non-volatile memory structure, a part of the charge storage layer is located on a top surface of the substrate.

In an embodiment of the invention, the non-volatile memory structure further includes a dielectric layer. The dielectric layer is disposed between the select gate and the substrate.

In an embodiment of the invention, the non-volatile memory structure further includes a first doped region and a second doped region. The first doped region is located in the substrate under the trench. The second doped region is located in the substrate on one side of the trench.

In an embodiment of the invention, in the non-volatile memory structure, a part of the first doped region is located in the substrate on two sides of the select gate. A top portion of the first doped region is lower than a top surface of the select gate.

In an embodiment of the invention, the non-volatile memory structure further includes a third doped region. The third doped region is located in the substrate on another side of the trench.

In an embodiment of the invention, the non-volatile memory structure further includes a well region. The well region is located in the substrate. The first doped region, the second doped region and the third doped region are located in the well region.

In an embodiment of the invention, in the non-volatile memory structure, a conductivity type of the well region is different from a conductivity type of the first doped region, the second doped region, and the third doped region.

In an embodiment of the invention, the non-volatile memory structure further includes a first lightly doped drain and a second lightly doped drain. The first lightly doped drain (LDD) is located in the substrate between the second doped region and the control gate.

The second lightly doped drain is located in the substrate between the third doped region and the control gate.

In an embodiment of the invention, in the non-volatile memory structure, a conductivity type of the first lightly doped drain and the second lightly doped drain is the same as a conductivity type of the first doped region and the second doped region.

Based on the above description, in the non-volatile memory structure of the invention, since the nitride layer serving as the charge storage layer is disposed on the two sidewalls of the trench, a memory device storing two bits in a single memory cell (two bits per cell) is realized. In addition, since the select gate and the control gate are disposed in the trench, the non-volatile memory structure may have a vertical channel and the embedded select gate, thus preventing a short channel effect and an over-erase phenomenon, and may have a higher cell density. In this way, the electrical performance and integration degree of the memory device may be effectively improved.

To make the aforementioned more comprehensible, several embodiments accompanied with drawings are described in detail as follows.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a cross-sectional view of a non-volatile memory structure according to an embodiment of the invention.

### DESCRIPTION OF THE EMBODIMENTS

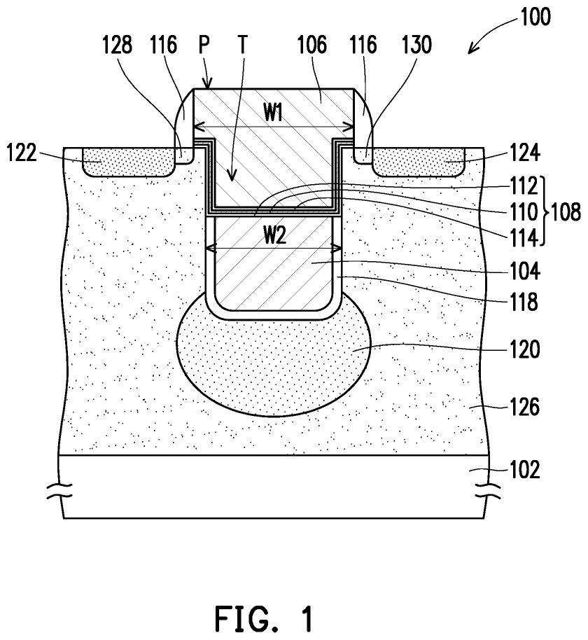

FIG. 1 is a cross-sectional view of a non-volatile memory structure according to an embodiment of the invention.

Referring to FIG. 1, the non-volatile memory structure 100 includes a substrate 102, a select gate 104, a control gate 106, and a charge storage layer 108. A trench T is formed in the substrate 102. The substrate 100 may be a semiconductor substrate such as a silicon substrate.

The select gate 104 is disposed in the trench T. Namely, the select gate 104 may be an embedded select gate. A material of the select gate 104 is, for example, a conductive material such as doped polysilicon, etc.

The control gate 106 is disposed in the trench T, and is located on the select gate 104.

The control gate 106 has a protrusion P protruding from a top surface of the substrate 102. A maximum width W1 of the protrusion P may be greater than a maximum width W2 of the trench T. In this way, a part of the control gate 106 may be located on the top surface of the substrate 102, and a cross-sectional shape of the control gate 106 may be a T-shape. A material of the control gate 106 is, for example, a conductive material such as doped polysilicon, etc.

The charge storage layer 108 is disposed between the control gate 106 and the select gate 104 and between the control gate 106 and the substrate 102. The charge storage layer 108 may be conformally disposed on two sidewalls of the trench T and on a top surface of the select gate 104. Moreover, a part of the charge storage layer 108 may be located on the top surface of the substrate 102. The charge storage layer 108 includes a nitride layer 110, an oxide layer 112, and an oxide layer 114. The nitride layer 110 is disposed on the select gate 104 and on the two sidewalls of the trench T, and may be used as a charge storage layer. The nitride layer 110 is a continuous structure. The oxide layer 112 is disposed between the nitride layer 110 and the select gate 104, and may be disposed between the nitride layer 110 and the substrate 102. The oxide layer 114 is disposed between the control gate 106 and the nitride layer 110.

Moreover, the non-volatile memory structure 100 may further include at least one of a spacer 116, a dielectric layer 118, a doped region 120, a doped region 122, a doped region 124, a well region 126, a lightly doped drain 128, and a lightly doped drain 130. The spacer 116 is disposed on a sidewall of the protrusion P. The spacer 116 may be a single-layer structure or a multi-layer structure. A material of the spacer 116 is, for example, silicon oxide, silicon nitride, or a combination thereof. The dielectric layer 118 is disposed between the select gate 104 and the substrate 102. A material of the dielectric layer 118 is, for example, silicon oxide.

The doped region 120 is located in the substrate 102 under the trench T. The doped region 120 may be used as a source line. A part of the doped region 120 may be located in the substrate 102 on two sides of the select gate 104. A top portion of the doped region 120 may be lower than the top surface of the select gate 104. The doped region 122 is located in the substrate 102 on one side of the trench T. The doped region 124 is located in the substrate 102 on the other side of the trench T. The well region 126 is located in the substrate 102. The doped region 120, the doped region 122 and the doped region 124 may be located in the well region 126. A conductivity type of the well region 126 may be different from a conductivity type of the doped region 120, the doped region 122, and the doped region 124. The lightly doped drain 128 is located in the substrate 102 between the doped region 122 and the control gate 106. The lightly doped drain 130 is located in the substrate 102 between the doped region 124 and the control gate 106. In some embodiments, the “lightly doped drain” may also be referred to as source/drain extension (SDE). The lightly doped drain 128 and the lightly doped drain 130 may be respectively located under the spacer 116. The lightly doped drain 128 and the lightly doped drain 130 may be located in the well region 126. A conductivity type of the lightly doped drain 128 and the lightly doped drain 130 may be the same as the conductivity type of the doped region 120, the doped region 122, and the doped region 124, and may be different from the conductivity type of the well region 126.

For example, the doped region 120, the doped region 122, the doped region 124, the lightly doped drain 128 and the lightly doped drain 130 may be N-type doped regions, and the well region 126 may be a P-type well region, but the invention is not limited thereto. In other embodiments, the doped region 120, the doped region 122, the doped region 124, the lightly doped drain 128 and the lightly doped drain 130 may be P-type doped regions, and the well region 126 may be an N-type well region.

Based on the above embodiment, it is known that in the non-volatile memory structure 100 of the invention, since the nitride layer 110 serving as the charge storage layer is disposed on the two sidewalls of the trench T, a memory device storing two bits in a single memory cell (two bits per cell) is realized. In addition, since the select gate 104 and the control gate 106 are disposed in the trench T, the non-volatile memory structure 100 may have a vertical channel and the embedded select gate 104, thus preventing a short channel effect and an over-erase phenomenon, and may have a higher cell density. In this way, the electrical performance and integration degree of the memory device may be effectively improved.

In summary, in the non-volatile memory structure of the above embodiment, since the nitride layer is disposed on the two sidewalls of the trench, and the select gate and the control gate are disposed in the trench, the electrical performance and integration degree of the memory device may be effectively improved.

It will be apparent to those skilled in the art that various modifications and variations can be made to the disclosed embodiments without departing from the scope or spirit of the invention. In view of the foregoing, it is intended that the invention covers modifications and variations provided they fall within the scope of the following claims and their equivalents.

What is claimed is:

1. A non-volatile memory structure, comprising:
a substrate, wherein there is a trench in the substrate;
a select gate, disposed in the trench;
a control gate, disposed in the trench and located on the select gate; and
a charge storage layer, disposed between the control gate and the select gate and between the control gate and the substrate, and comprising:
a nitride layer, disposed on the select gate and on two sidewalls of the trench, wherein the nitride layer is a continuous structure;
a first oxide layer, disposed between the nitride layer and the select gate; and
a second oxide layer, disposed between the control gate and the nitride layer.

2. The non-volatile memory structure as claimed in claim 1, wherein a material of the select gate comprises doped polysilicon.

3. The non-volatile memory structure as claimed in claim 1, wherein the control gate has a protrusion protruding from a top surface of the substrate.

4. The non-volatile memory structure as claimed in claim 3, wherein a maximum width of the protrusion is greater than a maximum width of the trench.

5. The non-volatile memory structure as claimed in claim 3, further comprising:
a spacer, disposed on a sidewall of the protrusion.

6. The non-volatile memory structure as claimed in claim 5, wherein the spacer is a single-layer structure.

7. The non-volatile memory structure as claimed in claim 5, wherein the spacer is a multi-layer structure.

8. The non-volatile memory structure as claimed in claim 1, wherein a part of the control gate is located on a top surface of the substrate.

9. The non-volatile memory structure as claimed in claim 1, wherein a cross-sectional shape of the control gate comprises a T-shape.

10. The non-volatile memory structure as claimed in claim 1, wherein a material of the control gate comprises doped polysilicon.

11. The non-volatile memory structure as claimed in claim 1, wherein the charge storage layer is conformally disposed on two sidewalls of the trench and on a top surface of the select gate.

12. The non-volatile memory structure as claimed in claim 1, wherein a part of the charge storage layer is located on a top surface of the substrate.

13. The non-volatile memory structure as claimed in claim 1, further comprising:
a dielectric layer, disposed between the select gate and the substrate.

14. The non-volatile memory structure as claimed in claim 1, further comprising:
a first doped region, located in the substrate under the trench; and
a second doped region, located in the substrate on one side of the trench.

15. The non-volatile memory structure as claimed in claim 14, wherein a part of the first doped region is located in the substrate on two sides of the select gate, and a top portion of the first doped region is lower than a top surface of the select gate.

16. The non-volatile memory structure as claimed in claim 14, further comprising:
a third doped region, located in the substrate on another side of the trench.

17. The non-volatile memory structure as claimed in claim 16, further comprising:
a well region, located in the substrate, wherein the first doped region, the second doped region, and the third doped region are located in the well region.

18. The non-volatile memory structure as claimed in claim 17, wherein a conductivity type of the well region is different from a conductivity type of the first doped region, the second doped region, and the third doped region.

19. The non-volatile memory structure as claimed in claim 14, further comprising:
a first lightly doped drain, located in the substrate between the second doped region and the control gate; and
a second lightly doped drain, located in the substrate between the third doped region and the control gate.

20. The non-volatile memory structure as claimed in claim 19, wherein a conductivity type of the first lightly doped drain and the second lightly doped drain is the same as a conductivity type of the first doped region and the second doped region.
